(19) United States
(12) Patent Application Publication
(10) Pub. No.: US 2026/0036627 A1
(43) Pub. Date: Feb. 5, 2026

(54) METHOD AND SYSTEM FOR MONITORING THE HEALTH OF A SOLENOID

(71) Applicant: SAIA-BURGESS LLC, VANDALIA, OH (US)

(72) Inventors: Kurtis David KEENER, Gahanna, OH (US); Adam STIENECKER, Tipp City, OH (US); Kenneth S. LEVINE, Tipp City, OH (US)

(21) Appl. No.: 19/351,953

(22) Filed: Oct. 7, 2025

Related U.S. Application Data
(63) Continuation of application No. PCT/US2023/018263, filed on Apr. 12, 2023.

(51) Int. Cl. G01R 31/34

(52) U.S. Cl. CPC G01R 31/34

(57) ABSTRACT

There is provided a method and system for monitoring the health of a solenoid and controlling the solenoid to compensate for a change in the health of the solenoid due to wear. The system including a sensor for detecting at least one parameter of a motion of the solenoid; and a control system for providing a control signal to the solenoid at a first time point, measuring at least one motion parameter of an actual motion of the solenoid driven by the provision of the control signal, and predicting a remaining life of the solenoid based on a difference between actual and target motion parameters of the motion of the solenoid.

### CROSS REFERENCE TO RELATED APPLICATIONS

This non-provisional patent application is a continuation application of PCT Application No. PCT/US2023/018263, filed with the USPTO on Apr. 12, 2023, which is incorporated herein by reference in its entirety.

### FIELD OF THE INVENTION

The present disclosure relates to solenoids and more specifically, to a method and system for monitoring the health of a solenoid.

### BACKGROUND

Solenoid actuators are electromagnetic devices that work to convert electrical energy into a mechanical pushing or pulling force or to the motion of an actuating element. When an electrical current is passed through the coil in a solenoid, it behaves like an electromagnet. The actuating element of the solenoid (which is located inside the coil) is driven to move relative to the coil by the magnetic flux setup within the coils. The force and speed of the movement of the actuating element is determined by the strength of the magnetic flux generated within the coil.

Solenoid actuators are typically used as basic components of automation systems and are specifically utilized in electromagnetically controlled industrial automation equipment. In the application of solenoids to high-speed automatic sorting equipment, high requirements are placed on the speed, dynamic response and accuracy of the solenoid.

In various applications of solenoid control, it is known to provide compensation in the form of a simple feedback loop. The feedback loops are provided to adjust the input provided to the solenoid. For example, it is known to directly utilize a delay in the output signal of a solenoid to control the start of the solenoid.

Existing solenoid systems generally lack a robust and effective means of monitoring the working state of solenoids, and as such these systems have no way of monitoring and assessing the health, accuracy and stability of the motion of the solenoid in response to control signals provided to the solenoid. This is a significant shortcoming within the traditional design of solenoids. As there are limited means for assessing the health of solenoids, it can be difficult to complete preventative maintenance on solenoids, and significant unexpected downtime can occur within automation systems due to the failure of the solenoid. It is therefore an object of the disclosure to provide a new method and system for monitoring the health of a solenoid

### SUMMARY OF THE INVENTION

According to an aspect, there is provided a method for monitoring the health of a solenoid, the method comprises measuring a first value of at least one motion parameter of a motion of the solenoid when the solenoid is actuated at a first time point, the actuation of the solenoid being driven by a first control signal that is provided to the solenoid, measuring a second value of the at least one motion parameter when the solenoid is actuated at a second time point, the actuation of the solenoid being driven by a second control signal that is provided to the solenoid, determining a remaining life of the solenoid based on a failure threshold of the at least one motion parameter and at least one first change trend of the at least one motion parameter, and generating a first warning signal to indicate that the remaining life is less than an acceptable remaining life of the solenoid.

According to another aspect, there is provided a system for monitoring the health of a solenoid, the system comprising: at least one sensor positioned to detect at least one characteristic of a motion of the solenoid, a control system connected to the solenoid and the sensor, the control system including at least one processor, memory in electronic communication with the at least one processor, and instructions stored in the memory that are executable by the at least one processor for: providing a first control signal to the solenoid at a first time point for driving a motion of the solenoid, receiving from the at least one sensor at least one motion parameter of a motion of the solenoid the motion being driven by the at least one first control signal, providing a second control signal to the solenoid at a first time point for driving a motion of the solenoid, receiving from the at least one sensor at least one motion parameter of a motion of the solenoid the motion being driven by the at least one second control signal, and generating a warning signal to indicate that a remaining life is less then an acceptable remaining life of the solenoid, the remaining life being determined based on a failure threshold of the at least one motion parameter and at least one first change trend of the at least one motion parameter.

### BRIEF DESCRIPTION OF THE DRAWINGS

Embodiments will now be described, by way of example only, with reference to the attached Figures, wherein:

FIG. 1A shows a flow-chart schematic of a first method for controlling a solenoid in accordance with an embodiment of the disclosure;

FIG. 1B shows a flow-chart schematic of an additional embodiment of the first method for controlling a solenoid provided in FIG. 1A;

FIG. 2A shows a flow-chart schematic of a method for monitoring the health of a solenoid in accordance with the embodiment of FIG. 1A;

FIG. 2B shows an additional flow-chart schematic of a method for monitoring the health of a solenoid according to the embodiment provided in FIG. 1A;

FIG. 3 shows a schematic diagram of the system and control system according to an embodiment of the present disclosure;

FIG. 4 shows a flow-chart schematic of the method for monitoring the health of a solenoid according to FIG. 1A, where the method includes a step of correcting at least one second control parameter of the second control signal;

FIG. 5 shows a flow-chart schematic of the method for monitoring the health of a solenoid according to FIG. 1A, where the method includes a step of generating a feedforward control signal;

FIG. 6A shows a control-flow diagram of the control system according to an embodiment of the present disclosure;

FIG. 6B shows a circuit diagram of an embodiment of a solenoid driving circuit for use with the solenoid of the present disclosure;

FIG. 7 shows a flow-chart schematic of a method for storing a dataset of at least one control parameter of the control signal in a database that includes a data table of solenoid parameters;

FIG. 8 shows a flow-chart schematic of a further embodiment of the second method for controlling a solenoid as provided in FIG. 2A;

FIG. 9 shows a diagram of a pulsed waveform that is provided as part of a pulsed width modulated control signal according to an embodiment of the present disclosure; and

FIG. 10 shows a plot of several sensed values of the at least one motion parameter of the solenoid according to an embodiment of the present disclosure.

### DETAILED DESCRIPTION OF THE PREFERRED EMBODIMENTS

For simplicity and clarity of illustration, where considered appropriate, reference numerals may be repeated among the Figures to indicate corresponding or analogous elements. In addition, numerous specific details are set forth in order to provide a thorough understanding of the embodiment or embodiments described herein. However, it will be understood by those of ordinary skill in the art that the embodiments described herein may be practiced without these specific details. In other instances, well-known methods, procedures and components have not been described in detail so as not to obscure the embodiments described herein. It should be understood at the outset that, although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described below.

Various terms used throughout the present description may be read and understood as follows, unless the context indicates otherwise: “or” as used throughout is inclusive, as though written “and/or”; singular articles and pronouns as used throughout include their plural forms, and vice versa; similarly, gendered pronouns include their counterpart pronouns so that pronouns should not be understood as limiting anything described herein to use, implementation, performance, etc. by a single gender; “exemplary” should be understood as “illustrative” or “exemplifying” and not necessarily as “preferred” over other embodiments. Further definitions for terms may be set out herein; these may apply to prior and subsequent instances of those terms, as will be understood from a reading of the present description. It will also be noted that the use of the term “a” or “an” will be understood to denote “at least one” in all instances unless explicitly stated otherwise or unless it would be understood to be obvious that it must mean “one”.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

The embodiments of the inventions described herein are exemplary (e.g., in terms of materials, shapes, dimensions, and constructional details) and do not limit by the claims appended hereto and any amendments made thereto. Persons skilled in the art will appreciate that there are yet more alternative implementations and modifications possible, and that the following examples are only illustrations of one or more implementations. The scope of the invention, therefore, is only to be limited by the claims appended hereto and any amendments made thereto.

The system as provided herein functions to monitor the health of a solenoid and to control the driving of this solenoid to compensate for the decline in the health of the solenoid due to the wear and deterioration of the components within the solenoid. In the embodiments of the system and method as provided herein, the system provides feed-forward control to monitor solenoid health and to compensate for the wear of the internal components and mechanism within the solenoid.

### Physical System

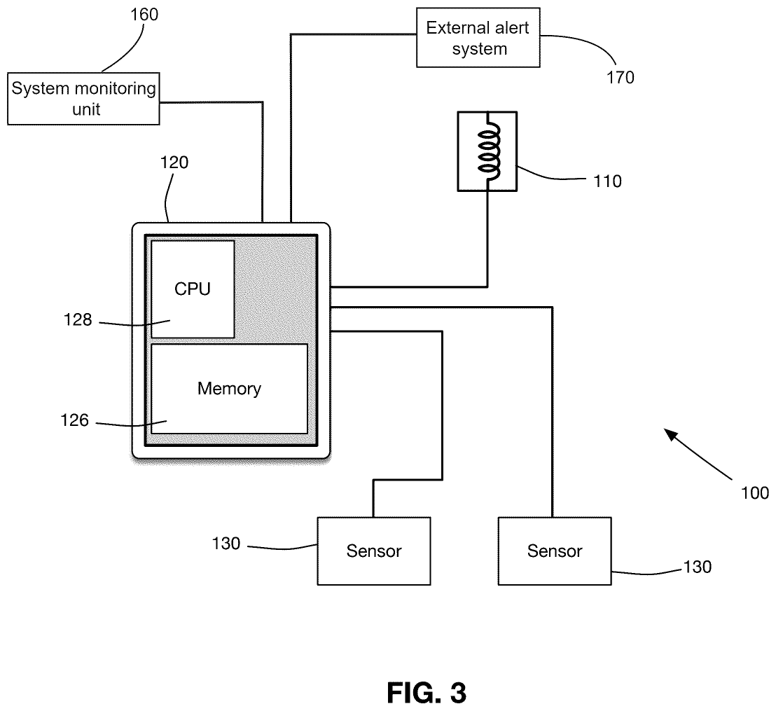

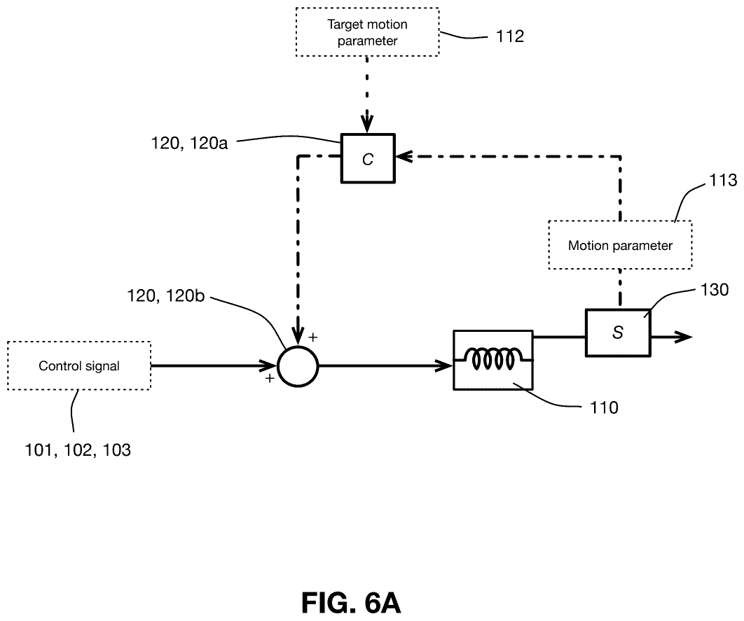

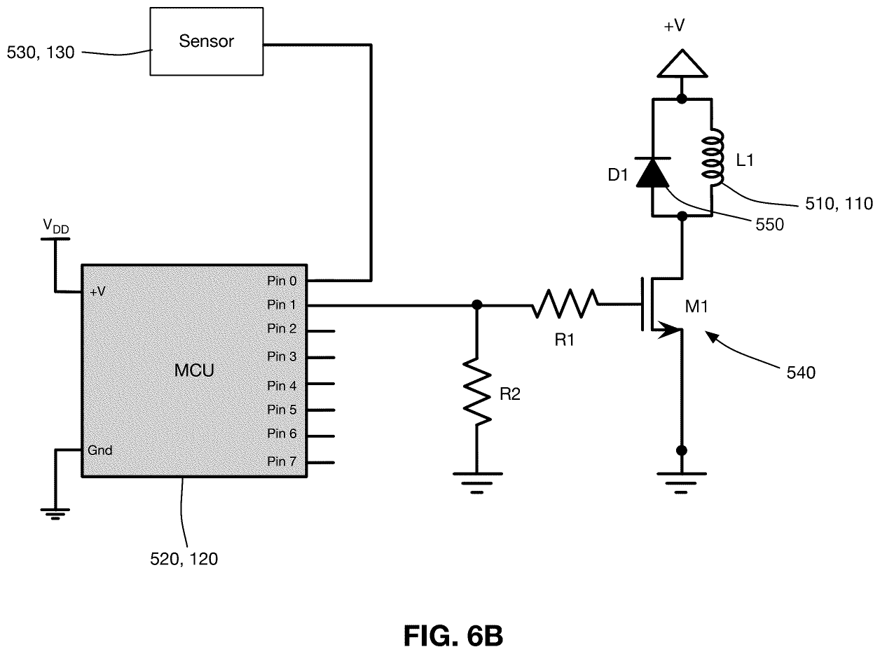

Referring to the embodiments provided in FIG. 3, the system 100 for monitoring the health of a solenoid 110 includes at least one sensor 130 and a control system 120. The at least one sensor 130 is positioned to detect one or more values of at least one motion parameter 113 of a motion of the solenoid 110 when the solenoid 110 is driven to move. In an embodiment, the control system 120 includes at least one processor, memory in electronic communication with the at least one processor, and instructions stored in the memory that are executable by the processor. In the specific embodiment provided in FIGS. 3 and 6A, the control system 120 has a number of physical and logical components including the at least one processor in the form of a central processing unit (“CPU”) 128 and the memory in the form of an internal memory (“Memory”) 126. The control system 120 is operably connected to the solenoid 110 and to the at least one sensor 130. The solenoid 110 includes a solenoid coil and an actuating element, where an electromagnetic force is generated within the solenoid coil of the solenoid 110 by providing a pulsed signal through the solenoid coil, where this electromagnetic force in turn drives a motion of the actuating element from a first solenoid position to a second solenoid position.

In an embodiment, the at least one sensor 130 and the solenoid 110 are electrically connected to the control system 120 for receiving one or more solenoid control signals provided by the control system 120, and for providing feed-forward control to the solenoid 110 according to the solenoid control signals provided by the control system 120. The at least one sensor 130 measures one or more values of at least one motion parameter 113, where the at least one motion parameter 113 is associated with and/or proportional to at least one aspect of a motion of the solenoid 110 that is driven by the provision of the control signal to the solenoid. The at least one motion parameter 113 can be associated with a characteristic of a motion of the solenoid 110, or it can be associated with a parameter of the control signal that drives the motion of the solenoid 110.

The at least one sensor 130 generates a signal that is proportional to the value of the at least one motion parameter 113 and provides this signal to the control system 120. It will be readily understood that the at least one sensor 130 can measure multiple, independent values of the at least one motion parameter 113, where each of these independent values is associated with an independent motion of the solenoid 110 that occurs at an independent time point. Each of the independent motions of the solenoid 110 can be driven by the provision of at least one control signal to the solenoid 110 from the control system 120.

### Method for Monitoring Health

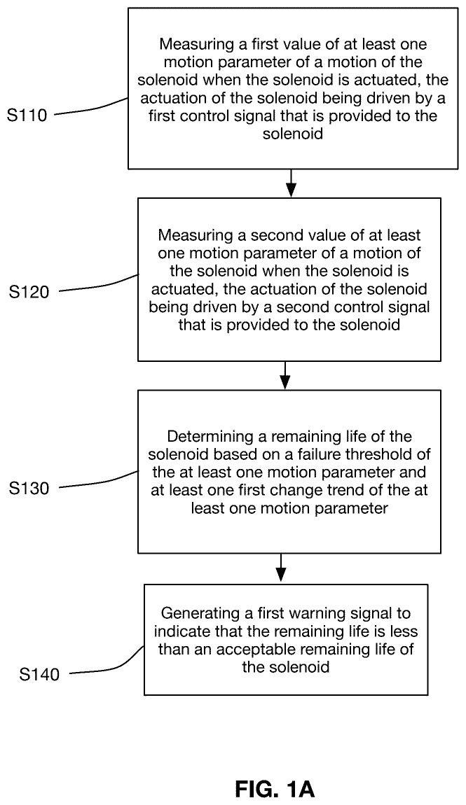

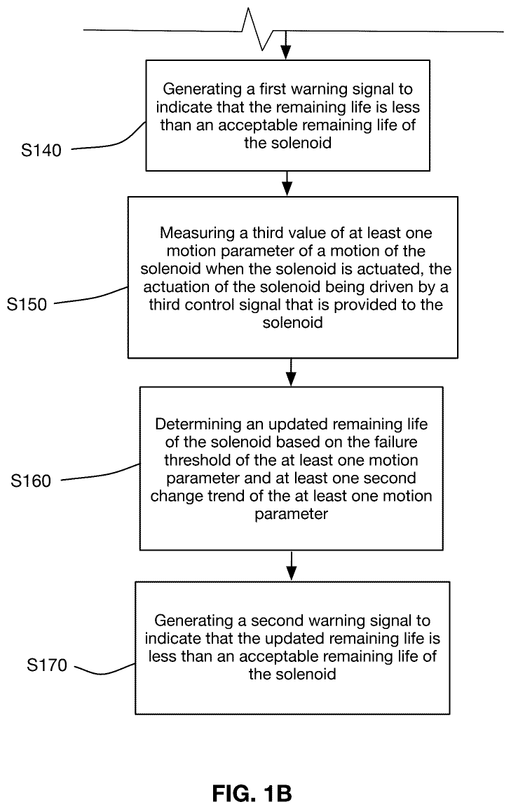

The control system 120 is generally programmed with a first set of computer-executable instructions for monitoring the health of the solenoid 110. Referring to FIG. 1A, there is provided a flowchart of an embodiment of the computer-executable instructions that are programmed in and stored on a memory of the control system 120. In this first embodiment, the instructions stored in the memory of the control system 120 are executable by the at least one processor of the control system 120 for, in a first step S110, measuring a first value of at least one motion parameter 113 of a motion of the solenoid 110 when the solenoid 110 is actuated at a first time point, where the actuation of the solenoid 110 is driven by a first control signal 101 that is provided to the solenoid 110. The first control signal 101 that is provided to the solenoid 110 at the first time point is defined by at least one first control parameter. The at least one first control parameter is set for realizing a target motion of the solenoid 110. Said another way, the target motion of the solenoid 110 that should occur in response to the provision of the first control signal 101 to the solenoid 110 is set by at least one first control parameter.

In the same embodiment, the instructions stored in the memory of the control system 120 are executable by the at least one processor of the control system 120 for, in a step S120, measuring a second value of the at least one motion parameter 113 when the solenoid is actuated at a second time point, where the actuation of the solenoid is driven by a second control signal 102 that is provided to the solenoid. Like the first control signal 101, the second control signal 102 is similarly defined by at least one second control parameter, where the at least one second control parameter is set for realizing the target motion of the solenoid.

The instructions stored in the memory of the control system 120 are executable by the at least one processor of the control system 120 for, in an additional step S130, determining a remaining life of the solenoid 110 based on a failure threshold of the at least one motion parameter 113 of the actual motion of the solenoid 110 and at least one first change trend of the at least one motion parameter 113, and in an additional step S140, generating a first warning signal to indicate that the remaining life is less than an acceptable remaining life of the solenoid 110.

In an embodiment, the second time point is a time after the motion of the solenoid associated with the provision of the first control signal 101 is completed.

In an embodiment, the at least one first change trend is determined based on the first value of the at least one motion parameter 113 at the first time point and the second value of the at least one motion parameter 113 at the second time point. For example, the at least one first change trend can be a rate of change of the at least one motion parameter 113, and the rate of change of the at least one motion parameter 113 is determined by dividing a difference of the first value of the motion parameter(s) and the second value of the motion parameter(s) by a difference between the first time point and the second time point.

In the embodiment of the control system provided in FIG. 1B, the memory of the control system 120 is further programmed with computer-executable instructions including, an additional sub-step S150 of measuring a third value of the at least one motion parameter 113 when the solenoid is actuated at a third time point via a third control signal 103 that is provided to the solenoid 110, a sub-step S160 of determining an updated remaining life of the solenoid based on the failure threshold of the at least one motion parameter 113 and at least one second change trend of the at least one motion parameter 113, and an additional sub-step S170 of generating a second warning signal to indicate that the updated remaining life is less than the acceptable remaining life of the solenoid.

In an embodiment, the third time point is a time after the motion of the solenoid associated with the provision of the second control signal 102 is completed.

In an additional embodiment, the third time point is a time after the second time point, and the second time point is a time after the first time point.

In an embodiment, the at least one second change trend is determined based on the third value of the at least one motion parameter 113 at the third time point, and at least one of the first value of the at least one motion parameter 113 at the first time point and the second value of the at least one motion parameter 113 at the second time point. For example, the at least one second change trend can simply be a rate of change of the at least one motion parameter 113, and is determined by dividing a difference between the third value of the motion parameter(s) and the second value of the motion parameter(s) by a difference between the third time point and the second time point.

### Failure Threshold

In an embodiment, the failure threshold of the at least one motion parameter 113 of the solenoid 110 is a value of the at least one motion parameter 113 that is indicative of a potential failure of the solenoid 110. The failure threshold of the at least one motion parameter 113 can be determined based on a maximum value of the at least one first control parameter of the first control signal 101 or the at least one second control parameter of the second control signal 102, and a corresponding, predicted value of the at least one motion parameter 113 that is associated with this maximum value of the at least one first control parameter or the at least one second control parameter.

In an alternate embodiment, the failure threshold of the at least one motion parameter 113 is determined from data provided by the manufacturer of the solenoid 110.

In another, additional embodiment, the step S130 of determining the remaining life of the solenoid based on the failure threshold and the at least one first change trend includes the steps of applying at least one curve-fitting step to the first value of the at least one motion parameter 113 at the first time point and the second value of the at least one motion parameter 113 at the second time point to generate a curve of the at least one first change trend, and applying the failure threshold of the at least one motion parameter 113 to the curve of the at least one first change trend.

In yet another additional embodiment, the step S160 of determining the updated remaining life of the solenoid 110 based on the failure threshold and at least one second change trend includes the steps of applying at least one curve-fitting step to the third value of the at least one motion parameter 113 at the third time point, the second value of the at least one motion parameter 113 at the second time point and the first value of the at least one motion parameter 113 at the first time point to generate a curve of the at least one first change trend, and applying the failure threshold of the at least one motion parameter 113 to the curve of the at least one first change trend. For example, the first, second, and third values of the at least one motion parameter 113 can be plotted on a graph where the x-axis is time and the y-axis is the at least one motion parameter 113. A curve-fitting step can be applied to these plotted points to determine a curve-of-best-fit equation for the first, second and third values. The failure threshold of the at least one motion parameter 113 is then input to the equation for this curve-of-best-fit to determine an associated failure time. It will be readily understood that this failure time could be expressed as value with units of time, or a value that is a number of cycles or actuations of the solenoid 110.

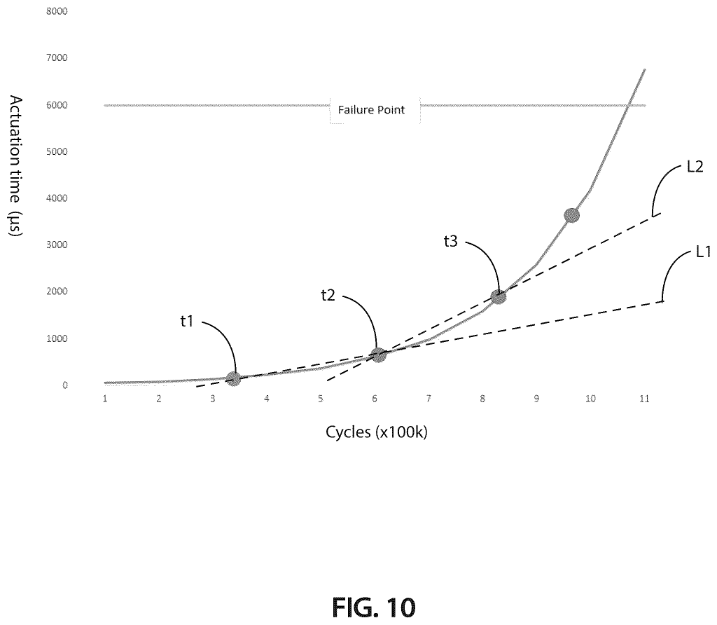

Referring to FIG. 10, there is provided a graphical plot of several values of the at least one motion parameter 113 of the solenoid 110 at several different time points. The plot provides the value of the at least one motion parameter 113 of the solenoid 110 (as measured by the at least one sensor 130) at various numbers of actuations (cycles) during the lifetime of the solenoid 110. In this exemplary embodiment, the at least one motion parameter (variable of the y-axis) is an actuation time of the solenoid 110. Each value of the actuation time is represented by a point and is associated with an independent actuation of the solenoid 110, where each independent actuation of the solenoid 110 is driven by the provision of an independent control signal (such as the first control signal 101), to the solenoid 110.

The plot in FIG. 10 also includes a first trend line (L1) that has been curve-fit (via the application of the at least one curve fitting step) to a first set of points, where the first set of points includes the values of the actuation time at t1 and t2. A difference between the value of the at least one motion parameter 113 at the points t1 and t2 can be used to determine a value of the first change trend of the at least one motion parameter 113. This first trend line (L1) can be considered as an exemplary embodiment of the at least one first change trend of the at least one motion parameter 113. The plot also provides a second trend line (L2) that has been curve-fit to a second set of points, where the second set of points includes the values of the actuation time at the points t2, and t3. Like the first change trend, the second change trend can be determined based on a difference between the at least one motion parameter 113 at the points t2, and t3. The second trend line (L2) can be considered as an exemplary embodiment of the at least one second change trend of the at least one motion parameter 113. Lastly, the plot includes a value of the at least one failure threshold of the at least one motion parameter 113. In this exemplary embodiment, the failure threshold is defined at a certain value of the actuation time of the solenoid 110 and is represented by a horizontal line on the plot. The remaining number of cycles (e.g., the remaining life) of the solenoid 110 can be determined for each of the first and second change trends based on this value of the at least one failure threshold. Each of the first trend line (L1) and second trend line (L2) can be extended to intersect with the horizontal line of the at least one failure threshold, where this intersection points will define the approximate number of cycles at which the at least one motion parameter 113 of the solenoid will reach the failure value (and will likely fail). In the exemplary embodiment provided in the plot, the slope of the second trend line is greater than the slope of the first trend line, and as such the change over time of the change trend means that the estimated remaining life of the solenoid 110 is decreasing over time, at an increasing rate.

While the embodiment in FIG. 10 specifically provides first and second trend lines (L1, L2) which are linear, it will be readily understood that various types of trend lines could be applied in characterizing the first and second change trends, determining the first and second failure points and estimating the remaining life and the updated remaining life associated with each of the first and second change trends. For example, in determining each of the first and second change trends, a curve can be fit between three or more points on the plot.

Said another way, the first trend line could be determined based on the values at points t₁, t₂ and t₃, and the second trend line could be determined based on the values at points t₂, t₃, and t₄. Once the first trend line and second trend line are determined, the intersection of each of the trend lines with the value of the at least one failure threshold can be determined to and estimating the remaining life and the updated remaining life.

In an alternate embodiment, the updated remaining life of the solenoid 110 is determined further based on a difference between the at least one first change trend and the at least one second change trend. Said another way, the updated remaining life is determined based on the failure threshold, the at least one second change trend of the at least one motion parameter 113, and the difference between the at least one first change trend and the at least one second change trend.

In another alternate embodiment, the updated remaining life of the solenoid 110 is determined further based on a difference between the at least one first change trend and the at least one second change trend. The difference between the at least one first change trend and the at least one second change trend can be a difference in various aspects of the respective change trends. In an exemplary embodiment, the difference between the at least one first change trend and the at least one second change trend is a difference between a slope of the at least one first change trend and a slope of the at least one second change trend. In another exemplary embodiment, the difference between the at least one first change trend and the at least one second change trend is a difference between a maximum (steepest) slope of the at least one first change trend and a maximum (steepest) slope of the at least one second change trend.

### Warning Signals

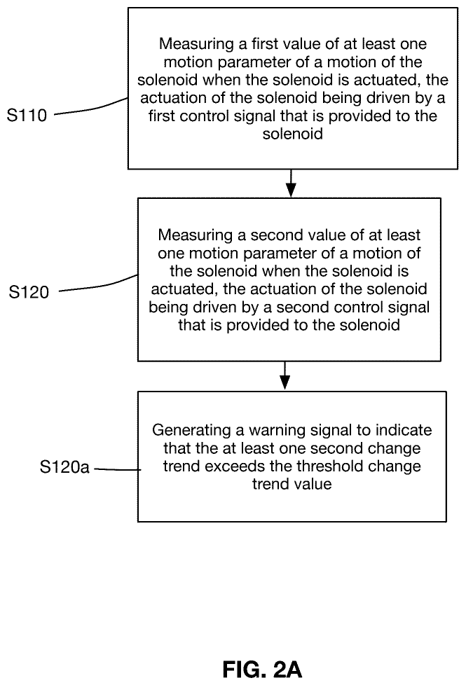

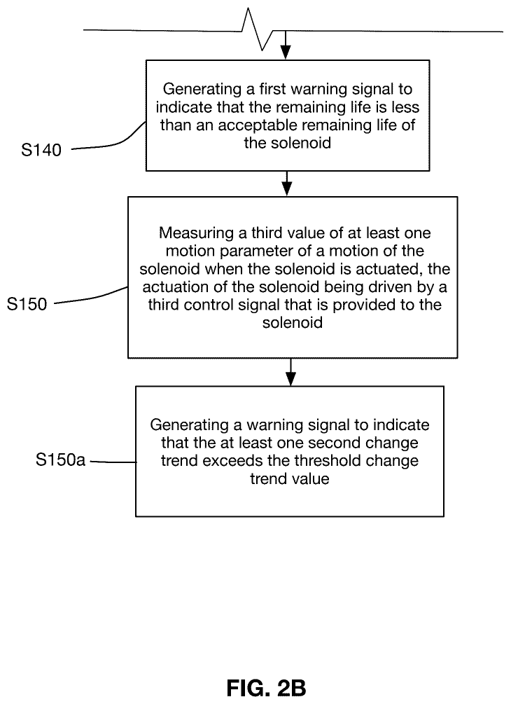

In the embodiment provided in FIG. 2A, the memory of the control system 120 is further programmed with computer-executable instructions where the step S120 of measuring a second value of the at least one motion parameter 113 further includes a sub-step S120a of generating a third warning signal to indicate that the at least one first change trend exceeds a threshold change trend value. The at least one threshold change trend value has a magnitude that is indicative of a potential failure of the solenoid 110.

In the embodiment provided in FIG. 2B, the memory of the control system 120 is further programmed with computer-executable instructions where the step S150 of measuring a third value of the at least one motion parameter 113 further includes a sub-step S150a of generating a third warning signal to indicate that the at least one second change trend exceeds the threshold change trend value.

### Feedforward Control

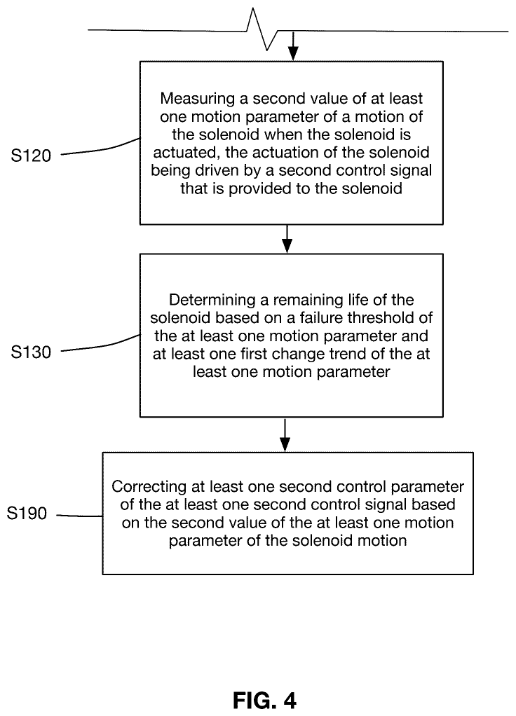

In the embodiment provided in FIG. 4, the memory of the control system 120 is further programmed with computer-executable instructions that include an additional sub step S190 of correcting at least one second control parameter of the at least one second control signal 102 based on the second value of the at least one motion parameter 113 of the motion of the solenoid 110. The step S190 may occur as an independent step as part of the computer-executable instructions stored in the memory of the control system 120, or may occur as a sub-step of the step S130 of determining a remaining life of the solenoid (as shown in FIG. 4).

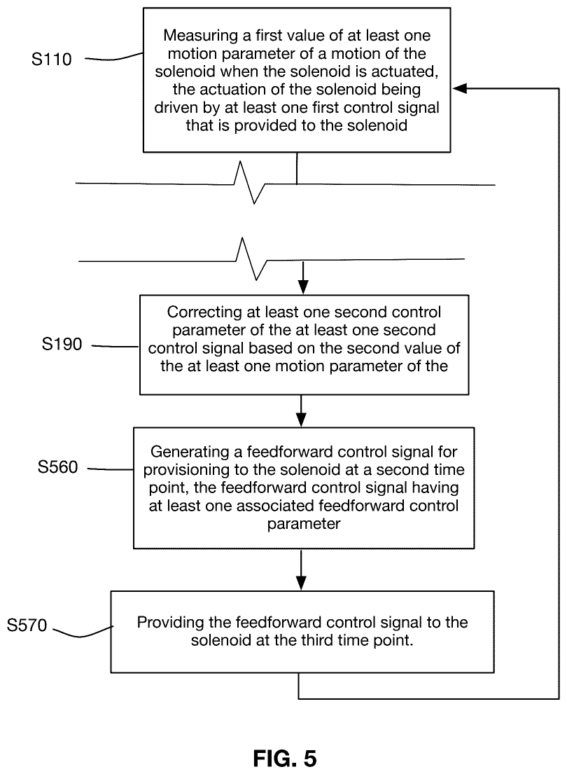

In the specific embodiment provided in FIG. 5, the memory of the control system 120 is further programmed with computer-executable instructions where the step S190 of correcting the at least one control parameter of the at least one second control signal 102 further includes the additional step S560 of generating a feedforward control signal for provisioning to the solenoid 110, where the feedforward control signal effectively acts as the control signal for driving an actuation of the solenoid 110. The feedforward control signal has at least one associated feedforward control parameter that is generated from the corrected at least one second control parameter, based on a difference between the second value of the at least one motion parameter 113 and a target value 112 of the at least one motion parameter 113.

In an embodiment of the step S560 of generating a feedforward control signal for provisioning to the solenoid 110, the at least one feedforward control parameter of the feedforward control signal is generated based on the corrected at least one second control parameter of the at least one second control signal 102 (which in turn is based on a difference between the second value of the at least one motion parameter 113 and the target value 112 of the at least one motion parameter). As the control system 120 is a feedforward control system, the feedforward control signal is not provided to the solenoid 110 to drive a subsequent, second motion of the solenoid 110 until a time point that is after the second time point. This time point that is after the second time point is defined at a time after the motion of the solenoid 110 (driven by the second control signal 102) is completed.

In an additional embodiment, the feedforward control signal is provided to the solenoid as the at least one third control signal 103 at the third time point. The feedforward control signal of a feedforward table is generated for provisioning to the solenoid at the third time point, where the third time point is at a time after the motion of the solenoid as driven by the second control signal 102 is completed.

In an embodiment, the feedforward control signal is provided as the third control signal to the solenoid 110 (in step S150) after the control system 120 has determined if a warning signal should be generated based on the remaining life of the solenoid (in step S140). Alternatively, the feedforward control signal is provided to the solenoid 110 as the third control signal (in step S150) before the control system 120 has determined if a warning signal should be generated (as in step S140).

In an embodiment where the at least one second control parameter is a plurality of second control parameters of the second control signal 102, only some of the plurality of second control parameters of the second control signal 102 are corrected. In this way, some but not all of the plurality of the feedforward control parameters are the same as the corresponding second control parameters of the second control signal 102.

In an embodiment, the control system 120 includes at least one control element in the form of a feed-forward controller for the solenoid 110. In an additional embodiment, the at least one feed-forward controller is combined with at least one additional feedback controller to realize a combined feedback performance. For example, the at least one additional feedback controller can be a proportional-integral-derivative (PID) controller.

A diagram of an exemplary embodiment of the closed-loop controller for feed-forward control of the solenoid 110 is provided in FIG. 6A. The diagram provides greater detail as to the control structure based on the steps of the methods provided in the embodiments of FIGS. 1 to 5B.

In the specific embodiment shown in FIG. 6A, the system includes the at least one sensor 130 that detects the second value of the at least one motion parameter 113 and, a first control element 120a of the control system 120 that analyzes the second value of the at least one motion parameter 113 to determine a difference between the second value of the at least one motion parameter 113 and the target value 112 of the at least one motion parameter. This first control element 120a utilizes the target value 112 of the at least one motion parameter 113 of the solenoid 110 as an input comparator to determine the difference between the second value of the at least one motion parameter 113 and the target value 112. The control system 120 also includes a second control element 120b, where the second control element 120b will, based on the control signal 101 and the detected difference between the second value of the at least one motion parameter 113 and the target value 112 of the at least one motion parameter 113, correct the at least one second control parameter of the second control signal 102 to generate the feedforward control signal. While the embodiment provided in FIG. 6A is specific to the second actual value of the motion parameters and the correcting of the second control signal 102, it will be readily understood that the above comparison of a value to a target value 112 for correcting a control parameter of a control signal could be similarly applied to the first control signal 101 and the first value of the at least one motion parameter 113 or the third control signal 103 and the third value of the at least one motion parameter 113.

### Change Trend of Control Signal Parameters

In an embodiment, the at least one motion parameter 113 of the solenoid 110 that is analyzed by the control system 120 is not a direct characteristic of the solenoid motion. Rather, the at least one motion parameter 113 is one or more of the at least one control parameters of the control signals that are provided to the solenoid. For example, the motion parameter is one of the at least one first control parameter and one of the at least one second control parameter of the first and second control signals 101, 102. In this way, the at least one first change trend of the at least one motion parameter 113 will be a change trend of at least one of the control parameters of the control signals, and the at least one second change trend of the at least one motion parameter 113 will be an additional change trend of the same at least one control parameter of the control signals provided to the solenoid 110. As provided above, these change trends will be determined based on a difference between the at least one control parameter of the first control signal 101 that is provided to the solenoid at the first time point, the at least one control parameter of the second control signal 102 that is provided to the solenoid 110 at the second time point, and the at least one control parameter of the third control signal 103 that is provided to the solenoid 110 at the third time point.

### Physical Structure and Processors

The at least one processor of the control system 120 may be any processor or controller and may be implemented as a singular processor or as a plurality of processors. The plurality of processors may be arrayed or distributed, and any processing function referred to herein may be carried out by one or by a plurality of processors, even though a single processor may be exemplified. Any method or application as herein described may be implemented using the computer readable/executable instructions as disclosed herein that are stored or otherwise held by such computer readable media and executed by the at least one processor.

In an embodiment, each of the first and second control elements 120a, 120b are separate controllers.

The memory of the control system 120 which stores the computer-executable instructions for the at least one processor may include computer readable media such as storage media, computer storage media, or data storage devices (removable and/or non-removable) such as, for example, magnetic disks, optical disks, or tape. The computer storage media may include volatile and non-volatile, removable and non-removable media implemented in any method or technology for storage of information, such as computer readable instructions, data structures, program modules, or other data. Examples of computer storage media include RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by an application, module, or both. Any such computer storage media may be part of the device or accessible or connectable thereto.

While the control system 120 is shown as a single physical computer system, it will be appreciated that the computer system of the control system 120 can include two or more physical computers in communication with each other. Accordingly, while the embodiment may show the various components of the control system 120 residing on the same physical computer, those skilled in the art will appreciate that the components can reside on separate physical computers.

In the specific embodiment provided in FIG. 6B, the control system 120 includes a microcontroller 520. The circuitry of the system includes a solenoid driving circuit that provides a connection between a singular solenoid 510, 110 and the microcontroller 520. The solenoid driving circuit facilitates the controlled actuation of the solenoid 510, 110 by the microcontroller 520. Within the solenoid driving circuit, the microcontroller 520 is connected to the solenoid 510, 110 via a MOSFET (M1) 540. The MOSFET 540 is connected therebetween for driving the solenoid 510, 110, and the solenoid 510, 110 is connected in parallel with a diode (D1) 550.

In an exemplary embodiment of the above-provided driving circuit, the solenoid 510, 110 is a 12V solenoid drawing 1.2 A of current, while the microcontroller unit is operated at 3.2V.

In an embodiment, the solenoid 110 is a linear solenoid (also known as a linear electromechanical actuator (LEMA)) that is structured to generate a straight-line linear movement.

In an alternate embodiment, the solenoid 110 is a rotary solenoid that is structured to generate a rotational movement of the actuating element of the solenoid 110 over some fixed angle. In this embodiment, the solenoid 110 is formed such that the first solenoid position is a first angular position and the second solenoid position is a second angular position.

In an embodiment, the solenoid 110 (whether linear or rotary) is either a holding solenoid that is continuously energised by a solenoid power source, or a latching type solenoid that is provided with a pulsed signal (an ON-and-OFF pulse).

In an embodiment, the solenoid 110 is a solenoid valve including the solenoid coil and a solenoid body. The solenoid body is formed for controlling fluid, and it is not limited to controlling liquid and gas. In an alternate embodiment the solenoid 110 is a solenoid control switch including the solenoid coil and a solenoid body.

In an embodiment, the at least one first, second and third control parameters of the first control signal 101, second control signal 102 and third control signal 103 each include a magnitude of a signal current of the associated control signal. In this same embodiment, the at least one feedforward control parameter of the feedforward control signal includes a magnitude of a signal current of the feedforward control signal.

In an embodiment, the at least one motion parameter 113 of the solenoid 110 includes at least one of an actuation time of the solenoid 110, a level of bounce of the solenoid 110 at a final actuation position of the solenoid, and a final velocity of the solenoid 110. In this same embodiment the target value 112 of the at least one motion parameter a target actuation time of the solenoid 110, a target level of bounce of the solenoid 110 at a final actuation position of the solenoid, and a target final velocity of the solenoid 110.

In an embodiment, if a magnitude of a difference between any of the first, second and third values of the at least one motion parameter 113 and the target value 112 is found to be outside a predetermined range or to exceed a predetermined acceptable value, the operating state of the solenoid 110 is said to be abnormal. When the operating state of the solenoid 110 is found to be abnormal, the step S190 of correcting the at least one control parameter of the control signal is completed by adjusting the at least one control parameter of the second control signal based on the difference between the actual value and target value 112 of the at least one motion parameter 113. The difference between the first, second and third values and the target value 112 of the at least one motion parameter 113 can occur at least partially due to a changing health of the solenoid over time. This changing health could be, for example, due to the wear over time of the electronic and mechanical elements in the solenoid 110. In this embodiment, once the magnitude of the difference between the first, second and third values and the target value 112 of the at least one motion parameter 113 increases to beyond a predetermined, acceptable level, the at least one control parameter of the control signal 101 will be adjusted to accommodate for the wear of the associated electronic and mechanical elements of the solenoid 110.

In a first, exemplary embodiment where the at least one motion parameter 113 includes an actuation time, if a difference between the second value of the actuation time and the target actuation time is such that the second value of the actuation time is still within an acceptable range of deviation from the target actuation time, then the at least one second control parameter of the second control signal 102 will not be corrected. In this embodiment, the acceptable range of deviation between the target value 112 and second value of the actuation time can be predefined based on particular operating characteristics and/or the particular operating ranges of the solenoid 110. In an additional, exemplary embodiment, if a difference between the second value of the actuation time and target actuation time is such that the target actuation time is greater then the second value of the actuation time, the at least one control parameter of the second control signal 102 is corrected to thereby generate the feedforward control signal.

### Pulse-Width Modulated (PWM) Control Signals

In an embodiment, at least one of the first, second and third control signals 101, 102, 103 is provided as a pulse-width modulated (PWM) control signal. At least one control parameter of the PWM control signal includes at least one pulse-width modulation parameter that characterizes at least one phase of the PWM control signal. The at least one pulse-width modulated parameter includes a magnitude and/or a duration of the at least one phase of the PWM control signal.

In an embodiment, at least one of the first, second and third control signals 101, 102, 103 and the feedforward control signal are provided as a pulsed control signal. In this embodiment, the at least one control parameter of the pulsed control signal includes at least a first pulse duration and a first pulse magnitude, and the at least one feedforward control parameter of the pulsed feedforward control signal includes at least a second pulse duration and a second pulse magnitude.

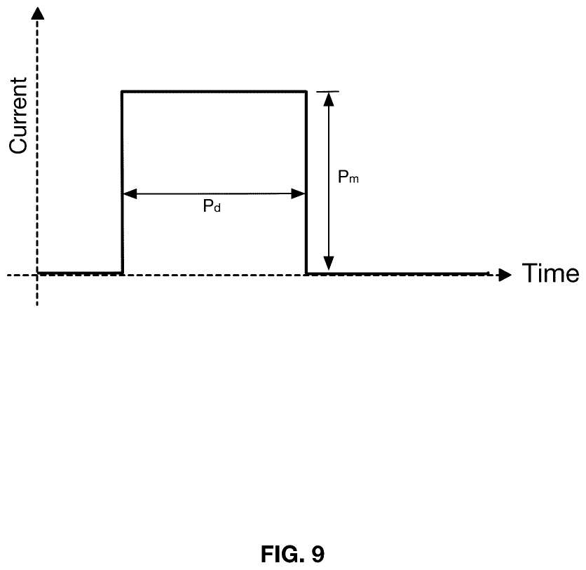

Referring to FIG. 9, a waveform diagram is provided that shows an exemplary embodiment of a pulse waveform provided by the control system 120 as a pulsed-width modulated (PWM) control signal. The waveform has a first pulse duration (Pa) defined by the PWM control signal and a first pulse magnitude (PM) defined by the PWM control signal. Repeated pulses of the PWM waveform are provided in order to drive the solenoid 110 from the first solenoid position to the second solenoid position, and to maintain the solenoid 110 in the second solenoid position. In this embodiment, the PWM control signal is provided as a PWM signal in order to reduce the overall power consumption of the solenoid coil in maintaining the position of the solenoid 110, thereby reducing the heat generated by the solenoid coil and allowing the solenoid to run more efficiently.

In an exemplary embodiment where the control signal is a PWM signal, the at least one pulse-width modulation parameter includes a magnitude of the at least one phase of the PWM control signal, and the magnitude of the at least one phase of the PWM control signal includes one of a current magnitude and a voltage magnitude of the PWM control signal in this phase.

In an embodiment where at least one of the first, second and third control signals 101, 102, 103 and the feedforward control signal are provided as a PWM control signal and a PWM feedforward control signal, each of the PWM control signal and the PWM feedforward control signal include one or more phases. The one or more phases of each of the PWM control signal and the PWM feedforward control signal include at least one of an acceleration phase for accelerating the actuating element (i.e., armature) of the solenoid 110, a braking phase for decelerating the actuating element of the solenoid 110, and a rest phase. The rest phase includes a zero current magnitude phase between successive phases with non-zero current magnitudes. In this embodiment, at least one control parameter of the PWM control signal includes at least one of an acceleration phase pulse duration or an acceleration phase pulse magnitude, or a deceleration phase pulse magnitude and a deceleration phase pulse duration.

In an exemplary embodiment, the PWM control signal includes a pulsed acceleration phase (with an associated acceleration pulse current) for accelerating the solenoid 110 from the first solenoid position towards the second solenoid position. In this embodiment, the at least one control parameter of the pulsed acceleration phase includes a pulse duration of the pulsed acceleration phase and a pulse magnitude of the pulsed acceleration phase. In this embodiment, the PWM control signal is provided with a pulsed acceleration phase to drive the motion of the solenoid 110 towards the second solenoid position.

In another exemplary embodiment, the PWM control signal includes a pulsed deceleration phase (with an associated deceleration pulse current) for decelerating the solenoid 110 from the second solenoid position towards the first solenoid position. In this embodiment, the at least one control parameter of the pulsed deceleration phase includes a pulse duration of the pulsed deceleration phase and a pulse magnitude of the pulsed deceleration phase. In this embodiment, the PWM control signal is provided with a pulsed deceleration phase to drive the motion of the solenoid 110 towards the first solenoid position.

In an alternate, exemplary embodiment where the at least one motion parameter 113 includes an actuation time and the target value 112 of the at least one motion parameter 113 is a target actuation time, the at least one control parameter of the PWM control signal is corrected when a difference between the actual actuation time and target actuation time is such that the actual actuation time is greater than the target actuation time. For example, the PWM control signal can include at least one of an acceleration phase and a deceleration phase, and the at least one control parameter of the PWM control signal can include at least one of an acceleration phase pulse duration and an acceleration phase pulse magnitude, or a deceleration phase pulse magnitude and a deceleration phase pulse duration. To compensate for the target actuation time being greater than the actual actuation time, the at least one pulse-width modulated control parameter can be corrected by either decreasing the acceleration phase pulse magnitude or increasing the deceleration phase pulse magnitude when generating the feedforward control signal.

In an additional, exemplary embodiment, the at least one motion parameter 113 includes both an actuation time and a level of bounce of the solenoid 110 when the solenoid 110 reaches a final actuation position. If the difference between the value of the actual actuation time and the value of the target actuation time is such that the actual actuation time is within an acceptable range of deviation from the target actuation time, but the actual level of solenoid bounce is greater then an acceptable level of solenoid bounce, the at least one pulse-width modulated control parameter of the PWM control signal is corrected. Specifically, the at least one pulse-width modulated control parameter is adjusted by either increasing the deceleration phase magnitude and/or the deceleration phase duration or decreasing the acceleration phase duration and/or the acceleration phase magnitude.

### System Warnings

As provided above, the control system 120 is formed to generate any of a first warning signal, a second warning signal, and a third warning signal in response to various values or changes in value of the remaining life of the solenoid 110, updated remaining life of the solenoid 110, the at least one first change trend, and the at least one second change trend. The first, second and third warning signals are referred to collectively, hereinafter as the system warning signals.

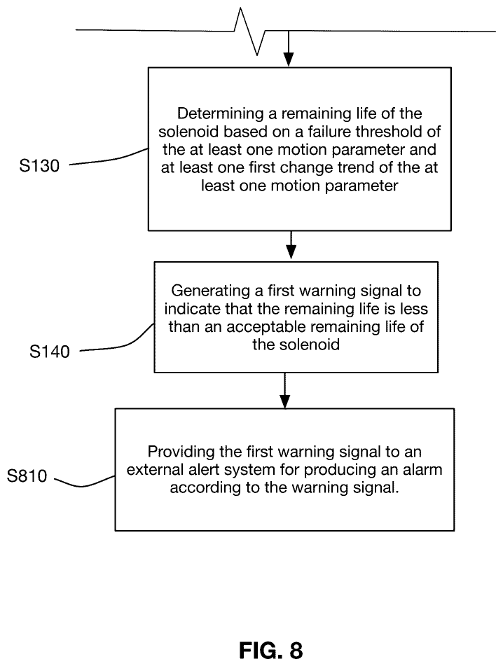

In an embodiment such as shown in FIG. 3, the control system 120 as disclosed herein is electrically connected to an external alert system 170, and the system warning signals are generated in the form of electric signals that are provided to the external alert system 170, where the external alert system 170 acts to alert a user. Referring to the flow-chart provided in FIG. 8, in the embodiments where the control system 120 is connected to the external alert system 170, the step S140 of generating a first warning signal further include the step S810 of providing the system warning signals to the external alert system 170. While this embodiment is specific to the step S810 occurring after the step S140, the step S810 may occur after any of the steps S140, S120a and S150a such that one of the system warning signals (either the first, second or third warning signal) is provided to the external alert system 170.

The control system 120 is configured to generate and send the system warning signals to the external alert system 170 when, as described above, it is determined that the remaining life is less than an threshold remaining life, and/or the updated remaining life is less then the threshold remaining life, and/or the first change trend is greater than the threshold change trend value, and/or the second change trend is greater than the threshold change trend value. Said another way, If the operating state of the solenoid 110 is found to be abnormal, the control system 120 sends the system warning signals to the external alert system 170, and the external alert system 170 will produce an alarm according to the system warning signals.

In an additional embodiment, the external alert system 170 is structured to produce an alarm in response to receiving one or more system warning signals from the control system 120. The external alert system 170 is structured such that the alarm can be in the form of a visual or audible indication that acts to alert a user. By proactively alerting a user via the warning signal and the external alert system 170, solenoid failure and unplanned downtime of systems that include the solenoid 110 can be reduced.

In an embodiment such as in FIG. 3, the control system 120 of the system as disclosed herein is communicatively connected to a system monitoring unit 160. In this embodiment, at least one of the steps S140, S170, S120a, or S150a (the steps of generating warning signals) further include where the warning signal is provided to the system monitoring unit 160. The system monitoring unit 160 includes internal memory on which each warning signal generated by the control system 120 is stored.

In an alternate embodiment, the system warning signals are not sent to the external alert system 170. Rather, the system warning signals are produced directly by the control system 120 and are in the form of visual signals or audible indication signals. The control system 120 is formed to generate a warning signal in the form of a visual and/or an audio indication signal, and in an exemplary embodiment, includes at least one of an integrated indicator light and an integrated speaker system, where the visual or audible form of the system warning signals are produced by the indicator light and the integrated speaker system.

In an embodiment of the system shown in FIG. 5, the memory of the control system 120 is further programmed with computer-executable instructions including an additional step S570 of providing the feedforward control signal to the solenoid 110 at the third time point. In this embodiment, the control signal that is provided at the third time point can effectively function as the first control signal 101. As shown in FIG. 5 once the feedforward control signal is provided to the solenoid at the third time point, the control flow of the system is such that the steps S110 to S140 are repeated, where the “measuring of a first value” in step S110 will be measuring a value of the at least one motion parameter 113 of an actual motion of the solenoid that is driven by the feedforward control signal. In this way, the feedforward control signal is provided to function as the first control signal 101 in the steps S110 to S140. In this embodiment, the memory of the control system 120 is further programmed with computer-executable instructions including a step of repeating at least steps S110 to S140 once the feedforward control signal is provided to the solenoid 110 as the third control signal.

### Database

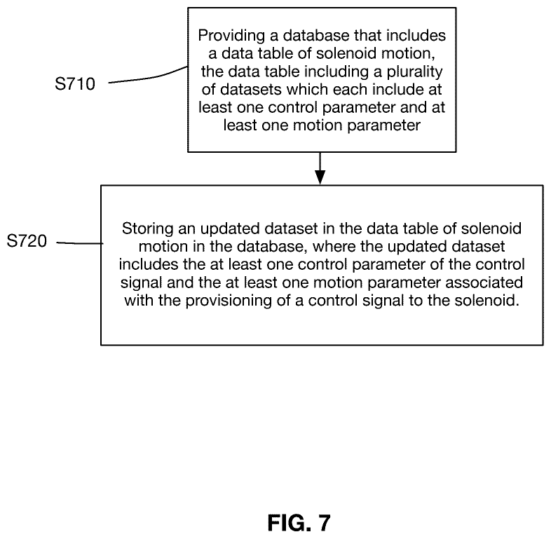

In an embodiment, the control system 120 further includes a database stored in the memory of the control system 120. Referring to FIG. 7, the memory of the control system 120 is further programmed with computer-executable instructions including a step S710 of providing the database, where the database includes a data table of solenoid motion of the solenoid 110. The data table includes a plurality of datasets, each of the datasets being associated with a control signal that has been provided to the solenoid 110. Each of the plurality of datasets include a value of at least one stored control parameter from a control signal that has been previously provided to the solenoid 110, and a value of at least one motion parameter 113 of an actual motion of the solenoid 110 that is associated with this previously provided control signal.

The database and associated data table of solenoid motion are provided as a feedforward lookup table, and function to provide a history of solenoid performance for one or more previously provided control signals. To realize more accurate feedforward control of the solenoid 110, the data table of solenoid motion can be adjusted periodically based on measured values of the at least one motion parameter 113 of the solenoid 110 in response to a control signal (such as the first control signal 101) being provided to the solenoid 110.

In an embodiment such as in FIG. 7, the memory of the control system 120 is further programmed with computer-executable including a step S720 of storing an updated dataset in the data table of solenoid motion in the database. The updated dataset including the value of at least one motion parameter 113 associated with the provision of another control signal to the solenoid 110. The updated dataset is stored once the control system 120 has received the value of the at least one motion parameter 113 of the actual motion of the solenoid 110 from then sensor 130.

In an exemplary embodiment of the data table and updated dataset, the data table includes a dataset associated with each of the first control signal 101, the second control signal 102, and the updated dataset is a dataset that includes a value of at least one control parameter of the third control signal 103 and a value of at least one motion parameter 113 associated with a motion of the solenoid 110 that is driven by the third control signal 103.

As noted above, the control system 120 of the system can be programmed for updating the plurality of datasets within the database for each new control signal that is provided to the solenoid 110. By updating the database to record the value of the at least one actual motion parameter for each new motion of the solenoid 110, the history of the solenoid 110 performance, as represented by the at least one motion parameter 113, can be monitored over a period of time.

In an embodiment, the memory of the control system 120 is further programmed with computer-executable instructions for storing a dataset for each feedforward control signal that is generated. By providing the data table with the at least one feedforward control parameter of each newly provided feedforward control signal, a history of updates of the control parameters is maintained. Based on the history of the updates of said control parameters of the control signal 101, certain conclusions can be made regarding the remaining life of the solenoid 110.

In an embodiment, by forming a dataset that includes more than two datasets of the at least one control parameter and two values of the at least one motion parameter 113, the performance of the solenoid 110 can be monitored for a time period that is greater than the time between the first time point and the second time point (e.g., the performance of the solenoid 110 can be monitored over a period of time that is greater than the period of time between two consecutive actuations of the solenoid 110).

In an embodiment, at least some of the plurality of datasets provided in the database are utilized to calculate a change trend of the at least one control parameter stored in the data table over the period of time that is greater than the time period between the first time point and the second time point. In this embodiment, the change trend of the at least one control parameter stored in the data table provides a trend over time of the performance of the solenoid 110. In an exemplary embodiment, the plurality of datasets includes at least one control parameter and a value of the at least one motion parameter 113 from a motion of the solenoid that is associated with each of the first, second and third control signals 101, 102, 103. In this way, the plurality of datasets can be used in determining the at least one second change trend of the at least one motion parameter 113.

Computer-executable instructions for implementing the method on the computer system as disclosed herein could alternatively be provided separately from the computer system, for example, on a computer-executable medium (such as, for example, an optical disk, a hard disk, a USB drive or a media card) or by making them available for downloading over a communications network, such as the Internet.

The above-described embodiments are intended to be examples of the present disclosure and alterations and modifications may be effected thereto, by those of skill in the art, without departing from the scope of the disclosure that is defined solely by the claims appended hereto.

### REFERENCE NUMBERS

101 first control signal
102 second control signal
103 third control signal
110 solenoid
112 target value
113 at least one motion parameter
120 control system
126 memory
128 central processing unit
130 sensor
160 system monitoring unit
170 external alert system
510 solenoid
520 microcontroller
540 MOSFET
550 diode

1. A method for monitoring the health of a solenoid, the method comprising:
measuring a first value of at least one motion parameter of a motion of the solenoid when the solenoid is actuated at a first time point, the actuation of the solenoid being driven by a first control signal that is provided to the solenoid;
measuring a second value of the at least one motion parameter when the solenoid is actuated at a second time point, the actuation of the solenoid being driven by a second control signal that is provided to the solenoid; and
determining a remaining life of the solenoid based on a failure threshold of the at least one motion parameter and at least one first change trend of the at least one motion parameter;
generating a first warning signal to indicate that the remaining life is less than an acceptable remaining life of the solenoid.

2. The method of claim 1, further comprising:
measuring a third value of the at least one motion parameter when the solenoid is actuated at a third time point via a third control signal;
determining an updated remaining life of the solenoid based on the failure threshold of the at least one motion parameter and at least one second change trend of the at least one motion parameter; and
generating a second warning signal to indicate that the updated remaining life is less than the acceptable remaining life of the solenoid.

3. The method of claim 2, wherein the second time point is a time after the motion of the solenoid associated with the provision of the first control signal is completed, and wherein the third time point is a time after the motion of the solenoid associated with the provision of the second control signal is completed.

4. The method of claim 1, wherein the at least one first change trend is determined based on the first value of the at least one motion parameter at the first time point, and the second value of the at least one motion parameter at the second time point.

5. The method of claim 4, wherein the step of measuring a second value of the at least one motion parameter further includes generating a warning signal to indicate that the at least one first change trend exceeds a threshold change trend value.

6. The method of claim 4, wherein the step of determining the remaining life of the solenoid based on the failure threshold and the at least one first change trend includes the steps of:
applying at least one curve-fitting step to the first value of the at least one motion parameter at the first time point and the second value of the at least one motion parameter at the second time point to generate a curve of the at least one first change trend; and
applying the failure threshold of the at least one motion parameter to the curve of the at least one first change trend.

7. The method of claim 3, wherein the at least one second change trend is determined based on the third value of the at least one motion parameter at the third time point, and at least one of the first value of the at least one motion parameter at the first time point, and the second value of the at least one motion parameter at the second time point.

8. The method of claim 7, wherein the step of determining the updated remaining life of the solenoid based on the failure threshold and at least one first change trend includes the steps of:
applying at least one curve-fitting step to the first value of the at least one motion parameter at the first time point and the second value of the at least one motion parameter at the second time point to generate a curve of the at least one first change trend; and
applying the failure threshold of the at least one motion parameter to the curve of the at least one first change trend.

9. The method of claim 7, wherein the step of measuring a third value of the at least one motion parameter further includes generating a warning signal to indicate that the at least one second change trend exceeds a threshold change trend value.

10. The method of claim 2, wherein the determining of the updated remaining life of the solenoid is further based on a difference between the at least one first change trend and the at least one second change trend.

11. The method of claim 10, wherein the difference between the at least one first change trend and the at least one second change trend is a difference between a slope of the at least one first change trend and a slope of the at least one second change trend.

12. The method of claim 1, wherein the step of determining the remaining life of the solenoid further includes a step of correcting at least one control parameter of the at least one second control signal based on the at least one second value of the motion parameter of the solenoid motion.

13. The method of claim 9, wherein at least one of the warning signal, the first warning signal and the second warning signal is in the form of any one of a visual signal, an audible indication signal, and an electric signal that is provided to an external alert system.

14. The method of claim 12, wherein the step of correcting the at least one control parameter of the at least one second control signal further includes generating a feedforward control signal having at least one feedforward control parameter, wherein the at least one feedforward control parameter of the feedforward control signal is generated by adjusting the at least one control parameter based on a difference between the at least one motion parameter and at least one target motion parameter.

15. The method of claim 14, wherein the feedforward control signal is provided to the solenoid as the at least one third control signal at the third time point.

16. The method of claim 1, wherein the at least one motion parameter includes at least one of an actual actuation time, an actual level of bounce of the solenoid at a final actuation position of the solenoid, and an actual final velocity of the solenoid.

17. The method of claim 12, wherein the at least one control parameter includes at least one PWM (pulse-width modulation) parameter that characterizes at least one phase of a PWM signal.

18. The method of claim 17, wherein the at least one PWM parameter includes a magnitude and/or a duration of the at least one phase of the PWM signal.

19. The method of claim 17, wherein the at least one PWM parameter includes a magnitude of the at least one phase of the PWM signal, and wherein the magnitude of the at least one phase of the PWM signal includes one of a current magnitude and a voltage magnitude.

20. The method of claim 17, wherein the at least one phase of the PWM signal includes at least one of an acceleration phase for accelerating an armature of the solenoid, a braking phase that decelerates the armature of the solenoid, and a rest phase, the rest phase including a zero current magnitude phase between successive phases with non-zero current magnitudes.

21. A system for monitoring the health of a solenoid, the system comprising:
at least one sensor positioned to detect at least one characteristic of a motion of the solenoid;
a control system connected to the solenoid and the sensor, the control system including at least one processor, memory in electronic communication with the at least one processor, and instructions stored in the memory that are executable by the at least one processor for:
providing a first control signal to the solenoid at a first time point for driving a motion of the solenoid;
receiving from the at least one sensor at least one motion parameter of a motion of the solenoid the motion being driven by the at least one first control signal;
providing a second control signal to the solenoid at a first time point for driving a motion of the solenoid; and
receiving from the at least one sensor at least one motion parameter of a motion of the solenoid the motion being driven by the at least one second control signal; and
generating a warning signal to indicate that a remaining life is less then an acceptable remaining life of the solenoid, the remaining life being determined based on a failure threshold of the at least one motion parameter and at least one first change trend of the at least one motion parameter.

22. The system of claim 21, wherein the instructions stored in the memory that are executable by the at least one processor further include:
providing a third control signal to the solenoid at a first time point for driving a motion of the solenoid;
receiving from the at least one sensor at least one motion parameter of a motion of the solenoid the motion being driven by the at least one third control signal; and
determining an updated remaining life of the solenoid based on the failure threshold of the at least one motion parameter and at least one second change trend of the at least one motion parameter; and
generating a warning signal to indicate that the updated remaining life is less then an acceptable remaining life of the solenoid.
